(19) United States
(12) Patent Application Publication
(10) Pub. No.: US 2014/0335635 A1
(43) Pub. Date: Nov. 13, 2014

(54) ELECTRONIC ASSEMBLIES INCLUDING A SUBASSEMBLY FILM AND METHODS OF PRODUCING THE SAME

(71) Applicants: Sridharan Venk, Salem, MA (US); Adam Scotch, Amesbury, MA (US); David Hamby, Andover, MA (US)

(72) Inventors: Sridharan Venk, Salem, MA (US); Adam Scotch, Amesbury, MA (US); David Hamby, Andover, MA (US)

(73) Assignee: OSRAM SYLVANIA INC., Danvers, MA (US)

(21) Appl. No.: 13/891,637

(22) Filed: May 10, 2013

(51) Int. Cl. H01L 23/00; H01L 33/48

(52) U.S. Cl. CPC H01L 24/80; H01L 33/483
USPC 438/27; 438/125

(57) ABSTRACT

Described herein are electronic assemblies including a subassembly film and methods for making the same. In some embodiments, a first subassembly is formed by placing an electronic die at a die placement location on a subassembly film. A second subassembly may be formed by placing the first subassembly at a subassembly placement position on a base layer, such that electrical contacts/traces on the first film overlap with electrical contacts/traces at a subassembly connection point on the base layer. Placement of the die on the subassembly film may be performed with automatic placement machinery that has a placement accuracy that is greater than that required to place the first subassembly on the base layer. As a result, the costly and time consuming manual inspection of die placement may be avoided.

### TECHNICAL FIELD

This application is generally drawn to electronic assemblies including a subassembly film and, more particularly, to methods for assembling microelectronic assemblies using a subassembly film.

### BACKGROUND

Electronic assemblies often include one or more electronic dies (hereafter, “die” or “dies”) that are located at appropriate locations on driving electronics, such as a circuit board. Such assemblies may be manufactured using surface mount technology component placement systems, otherwise known as “pick-and-place” systems. Those systems may utilize a pneumatic suction head to pick an electronic component such as a die from one location, and place it at another desired location, such as on appropriate contacts on the surface of a circuit board.

Although pick-and-place systems are useful, various factors impact whether they are economical to use in a production setting. In the construction of microelectronic assemblies, for example, a plurality of small dies may need to be placed over a relatively large area. In such instances, the cost of placing each die using conventional pick-and-place systems may increase as the number of dies increases, the size of the dies decreases, the size of the contacts at the die placement location decreases, and/or as the area over which the dies are to be placed increases. Any of these factors may dictate the use of a highly sensitive pick-and-place system that may include sophisticated software, sensors, and/or control systems. As a result, pick-and-place systems suitable for producing microelectronic assemblies may be expensive and slow.

Even if a highly sophisticated system is employed, costly and time consuming manual inspection may be required when conventional pick-and-place methods are used to produce microelectronic devices that include small dies that are distributed over a relatively large area. Such inspection may be needed to ensure that the placement, bonding and/or electrical connection of the dies are proper, particularly when the faulty placement and/or bonding of a single die may render the whole electronic device inoperable. It may also be difficult to rework assemblies that are formed using conventional pick-and-place technology. As a result, a single inaccurate placement/orientation of a die may require disposal of an entire microelectronics assembly. This may reduce overall production yields and further increase the cost of producing microelectronic assemblies using conventional pick-and-place technology.

Conventional pick-and-place technology may therefore be economically unattractive for the production of microelectronic devices, particularly those in which a multitude of small electronic dies are arranged over a relatively large area. Area array lighting devices that employ light emitting diode (LED) technology are one example of such devices. Such devices may include myriad (e.g., hundreds) of small (e.g., micron scale) light emitting diode dies that are disposed over a relatively large (e.g., 6 inch by 6 inch) circuit board. Assembly of such a device may thus require careful alignment and placement of the bond pads of each LED die at corresponding contact locations on the circuit board. Although conventional pick-and-place systems may be used to produce such devices, highly complex and sensitive pick-and-place machinery as well as manual inspection may be needed to ensure that production yields are sufficiently high.

### BRIEF DESCRIPTION OF THE DRAWINGS

Reference is now made to the following detailed description, which should be read in conjunction with the following figures, wherein like numerals represent like parts.

FIG. 1 is a flow diagram of an electronic device assembly method in accordance with the present disclosure.

FIGS. 2A through 2J diagrammatically illustrate the production of an exemplary electronic assembly using an assembly method in accordance with the present disclosure.

FIGS. 3A-3B diagrammatically illustrate an exemplary electronic assembly including multiple die placements, consistent with the present disclosure.

FIG. 4 diagrammatically illustrates an exemplary conductive trace design for a subassembly consistent with the present disclosure.

FIGS. 5A and 5B illustrate electronic assemblies including one or more of the subassemblies of FIG. 4.

Although the following detailed description will proceed with reference being made to illustrative embodiments, many alternatives, modifications, and variations thereof will be apparent to those skilled in the art.

### DETAILED DESCRIPTION

The present disclosure generally relates to electronic assemblies that include a subassembly film, and methods for producing the same. As will be described in detail below, the methods described herein may include placing and/or joining one or more electronic dies on/to a subassembly film, so as to form a first subassembly. Once formed, a first subassembly may be used to form an electronic assembly. For example, one or more of the first subassemblies may be placed at appropriate locations on a base layer (e.g., a flexible or rigid circuit board) that includes electrical connections for driving the die(s). In this way, the first subassemblies may be used to form a second subassembly, which may form all or a portion of an electronic device such as a lighting panel and/or an area array lighting device. Accordingly, the present disclosure describes modular approaches to forming electronic assemblies in which first subassemblies including one or more dies and subassembly film are formed, and which may be used in the subsequent production of electronic assemblies such as lighting panels. Such methods may enable rapid and/or facile production of electronic assemblies including one or a plurality of small dies, potentially without the need for manual inspection.

As used herein, the term “electronic assembly” is used to refer to an assembly of electronic components, such as a circuit board, electronic die, other types of electronic components (e.g., transistors, capacitors, resistors, etc.), combinations thereof, and the like. Individual electronic assemblies may form all or a part of an electronic device. In the latter case, multiple electronic assemblies may be connected so as to form all or a part of an electronic device.

The term, “electronic device” is used to refer to any type of device that accomplishes its purpose electronically. Electronic devices include but are not limited to lighting panels, area array lighting devices, automotive dash boards, tail and headlight panels, flat panel displays, combinations thereof, and the like.

The terms “electronic die” and “die” and “chip” are interchangeably used herein to refer to a small block of semiconductor material on which an electronic circuit or device is fabricated, e.g., an integrated circuit die or an LED die. Such electronic dies may include additional features such as electrical contacts, or be combined in a packaged device with lead frames, mounting structures, or optically active components. A microelectronic die refers to an electronic die having a major dimension of less than 1 mm. The present disclosure focuses on the use of bare die, packaged light emitting diodes (LED dies), and a wide range of electronic dies, including but not limited to micro scale electronic devices such as chip scale packages. The term “chip scale package” is used herein to refer to an electronic die that is mounted to a second electrical structure such as a lead frame or molded package such that the entire subassembly of die and structure is on the same size scale as the die.

The term “macro trace” is used herein to refer to electrical contacts/traces that have a line width and/or spacing that is greater than or equal to about 100 microns. In contrast, the term “micro trace” is used herein to refer to electrical contacts/traces that have a line width and/or spacing that is less than 100 microns.

The term “subassembly film” is used herein to refer to a film onto which an electronic die may be placed and joined. Subassembly films suitable for use in the present disclosure may be manufactured from any suitable material. Non-limiting examples of such materials include polyesters such as unoriented, uniaxially oriented, and biaxially oriented polyethylene terephthalate (PET) and polyethylene naphthalate (PEN), epoxides, epoxide composites, polyimide (PI) films such as KAPTON™ produced by DuPont, polyamide (PA) films (“e.g., nylon), acrylate films, copolymer films (e.g., acrylate polyether copolymer), combinations thereof, and the like. Without limitation, the subassembly films described herein are preferably formed from PET, PI, PEN or a combination thereof. In some embodiments, the subassembly film is formed from PET.

In some embodiments, the subassembly films may soften and/or become tacky upon the application of heat. For example, the subassembly films may soften and/or become tacky at a temperature ranging from about 20° C. to about 70° C., more particularly, from about 30° C. to about 60° C., from about 30° C. to about 50° C., or even about 40° C. This softening/tackifying may facilitate joining the subassembly film to other components, such as an electronic die, a base layer, a cover film (coverlay), or a combination thereof. For example, a die placed on a softened/tackified subassembly film may stick to and/or become partially embedded within the surface of the subassembly film. The microelectronic die may therefore be retained by chemical and/or physical interaction with the heated subassembly film. Similarly, a softened/tackified subassembly film may adhere and/or conform to a base layer and/or cover film with which it is in contact.

Of course, the subassembly films described herein need not be configured to soften and/or become tacky upon the application of heat. Indeed, the subassembly film may be attached to and/or retain a die in some other manner, such as with the application of pressure, and/or via an adhesive, fastener, conductive material, or a combination thereof. For example, an adhesive layer may be present on one or more surfaces of the subassembly film. A die applied to the subassembly film may contact and stick to such adhesive layer, thus retaining the die on the subassembly film. Non-limiting examples of suitable adhesives that may be applied to the surface of a subassembly film include acrylic adhesives, epoxy adhesives, and combinations thereof. Alternatively or additionally, a die may be adhered to a subassembly film using one or more conductive materials, such as but not limited to copper, silver, gold, silver-filled epoxy, conductive inks, CP-300 interconnect paste available from Hitachi Chemical, combinations thereof, and the like. Without limitation, the subassembly films preferably soften upon the application of heat, and may be attached to or retain a die with or without an adhesive/conductive material. Similarly, the subassembly film may be joined to a base layer and/or cover film with an adhesive, conductive material, a mechanical fastener, or a combination thereof.

The subassembly films described herein may further include electrical traces and/or contacts (hereinafter, contacts/traces). In some embodiments, such electrical contacts/traces may include macro traces, micro traces, or a combination thereof. The electrical contacts/traces on the subassembly film may define one or more placement locations for a die. For example, the placement location may be defined by a gap between the contacts/traces. In such instances, the configuration and spacing of the contacts/traces on each side of the gap may coincide with the configuration/spacing of bond pads on a microelectronic die. The gap may be configured such that contacts/traces on each side of the gap contact corresponding bond pads on a microelectronic die. The contacts/traces on either side of the gap may further include one or more regions for making electrical contact with corresponding contacts/traces at a subassembly connection site on a base film. In some embodiments, the contacts/traces on the subassembly film include a combination of micro and macro traces, wherein the micro traces define a gap for the placement of a die (i.e., a die placement location), and macro traces extend from the micro traces to define regions for making electrical contact with corresponding contacts/traces at a subassembly connection site of a base film.

In any case, the contacts/traces may be formed on an upper or lower surface of the subassembly film. Without limitation, the contacts/traces are preferably formed on the upper surface of the subassembly film, such that electrical contact between the contacts/traces and corresponding bond pads of an electronic die may be made when the die is placed on the subassembly film.

The subassembly films described herein may also be configured to maintain a desired degree of coplanarity under load, i.e., a desired difference in the height of electrical contacts on respective sides of a gap when a die is placed on the gap. Without limitation, the subassembly film is configured to maintain a coplanarity under load of 1, i.e., to maintain equal height of the contacts on both sides of the gap when a die is placed on the gap. In other embodiments, the subassembly film may be configured to maintain a coplanarity under load ranging from about 0.9 to 1.1, about 0.95 to 1.05, or even about 0.975 to about 1.125, i.e., to maintain a height difference between contacts on respective sides of a gap that is less than or equal to about 20%, 10% or even about 5%, when a die is placed on the gap.

Coplanarity may depend on the size of a die to be supported on the subassembly film, and a minimum width of the gap between the electrical contracts on the subassembly film. In some embodiments, coplanarity may be 35% or less, such as about 25% or less, about 20% or less, about 15% or less, about 10% or less, or even about 5% or less, relative to the minimum gap width. Accordingly, for a gap having a minimum width of 100 microns, a coplanarity of 25% of the minimum gap width would indicate a coplanarity of 25%. That is, the difference in height between the electrodes on either side of the 100 micron gap would vary by less than or equal to 25 microns.

Coplanarity may be related to the elastic modulus of the material(s) used to form the subassembly film. In general, materials with relatively high elastic modulus are stiffer than materials with relatively low elastic modulus, and thus may be better able to maintain coplanarity under load. Without limitation, the materials used to form the subassembly films described herein have an elastic modulus ranging from about 0.1 million pound force per square inch (Mlbf/in²) to about 5 Mlbf/in², such as about 0.3 Mlbf/in² to about 5 Mlbf/in², about 0.5 Mlbf/in² to about 5 Mlbf/in², about 1 Mlbf/in² to about 2.5 Mlbf/in², or even about 1 Mlbf/in² to about 2 Mlbf/in². Of course, such ranges are exemplary only, and films having any suitable elastic modulus may be used.

The subassembly films described herein may be flexible or rigid. As used herein, the term “flexible” when used in connection with a film means that the film is stiff enough to carry a die without bending, but is capable of conforming with and/or adhering to a base film. In some embodiments, subassembly films may be considered to conform and/or adhere to a base film when they have a minimum peel strength of about 0.5 kilogram force centimeter (kgf-cm) (e.g., about 0.6 kgf-cm, about 0.7 kgf-cm, about 0.8 kgf-cm, about 0.9 kgf-cm, etc.) when applied to the base film. Without limitation, the subassembly films described herein preferably are flexible films, including but not limited to polyester films such as PET, PEN, and combinations thereof.

The peel strength of the subassembly film may in some embodiments be controlled so as to achieve a desired balance between stiffness and coplanarity. In this regard, subassembly films that are capable of conforming to a base film to a greater degree (e.g., have a minimum peel strength substantially exceeding 0.5 kgf-cm) may have a relatively low stiffness, whereas subassembly films that may conform to a base film to a lesser degree (e.g., have a minimum peel strength of about 0.5 kgf-cm or less) may have a relatively high stiffness. Subassembly films that have high conformability may have insufficient stiffness to support a die, and may be unsuitable for use with pick-and-place technology. In contrast, subassembly films having high stiffness may support a die, but may be unable to sufficiently conform to a base film. Therefore in some embodiments, the subassembly films described herein have an elastic modulus, minimum peel strength, and coplanarity within the foregoing ranges.

The subassembly films described herein may also be transparent to light in one or more regions of the electromagnetic spectrum. For example, the subassembly film may transmit greater than or equal to 50% of light in the ultraviolet, visible, and/or infrared regions of the electromagnetic spectrum. In some embodiments, the subassembly film transmits greater than or equal to about 50 to about 100%, such as about 60 to about 100%, about 70 to about 100%, about 80 to about 100%, about 90 to about 100%, about 95 to about 100%, about 98 to about 100%, or even about 99 to about 100% of light in one or more of such regions of the electromagnetic spectrum. In instances where a die to be adhered to the subassembly film is configured to emit light in one or more of such regions (e.g., the die is an LED die), the subassembly film may be configured to exhibit transparency within the foregoing ranges for all or a portion of the light emitted by such die.

The term, “first subassembly” is used herein to refer to a subassembly layer with at least one die placed thereon. While the first subassemblies described herein preferably include a die bound to a subassembly layer (e.g., across a gap defined by contacts/traces on the subassembly layer), such a configuration is not required. Indeed, the term first subassembly encompasses structures in which a die is placed on a subassembly film, but is not bound to such film.

The term “base layer” is used herein to refer to a substrate that may support a first subassembly, and which includes electrical contacts/traces for driving one or more dies and/or other components of an electronic device. Accordingly, the base layer may be a rigid or flexible circuit board for all or a portion of an electronic assembly and/or device. In some embodiments, the base layer is a rigid or flexible circuit board for all or a portion of a lighting device, such as an area array lighting panel.

Any suitable materials may be used to form the base layers described herein. As non-limiting examples of such materials, mention is made of polyesters such as unoriented, uniaxially oriented, and biaxially oriented polyethylene terephthalate (PET) and polyethylene naphthalate (PEN), epoxies and epoxide composites such as glass epoxy sheeting (e.g., FR4), polyimide (PI) films such as KAPTON™ produced by DuPont, polyamide (PA) films (“e.g., nylon), acrylate films, copolymer films (e.g., acrylate polyether copolymer), metallic substrates, copper clad substrates, combinations thereof, and the like. Without limitation, the base layers described herein are preferably formed from PET, PEN, PI, or a combination thereof. In some embodiments, the base layers described herein are formed from PET.

As noted above, the base layer may include electrical contacts/traces formed on a surface thereof. Those contacts/traces may form all or a part of the driving electronics for an electronic device, including but not limited to lighting devices such as an area array lighting panel, motherboards, graphics cards, automobile dash boards, automobile head and tail light panels, flat panel displays, combinations thereof, and the like. In some embodiments, the electrical contacts/traces on the base layer form all or a part of the driving electronics of an area array lighting panel.

The electrical contacts/traces on the base layer may define one or more subassembly connection sites. Without limitation, a subassembly connection site may be defined by a gap in the contacts/traces of the base layer. In such instances, the contacts/traces on either side of the gap may be positioned and/or configured to correspond to at least a portion of the contacts/traces on the subassembly film. In particular, the contacts/traces at a subassembly connection site on the base film may be placed and configured such they overlap with at least a portion of corresponding contacts/traces on a subassembly film, when a first subassembly is placed on the base layer at such subassembly connection site. Without limitation, the contacts/traces on the base film are preferably configured to overlap with one or more regions of contacts/traces on a subassembly film which are designated for making electrical contact between a first subassembly and the base film.

In some embodiments the base layer includes at least one subassembly connection site that is defined by a gap between two macro traces, and the electrical contacts/traces of the subassembly film may include a combination of micro traces and macro traces. The micro traces of the subassembly layer may define a gap for placement of a die, and the macro traces of the subassembly layer may define regions for making electrical contact with the macro traces at such subassembly connection site. At least a portion of the macro traces of the subassembly film may overlap with corresponding macro traces of the base layer when the first subassembly and the base layer are overlaid and/or joined. As described later, the macro traces of the subassembly film and base layer may be electrically connected, e.g., with one or more wires, conductive material (e.g., a conductive solder, a conductive paste, a conductive ink, etc.), combinations thereof and the like. Without limitation, the width of the macro traces at a subassembly connection site on the base layer is preferably larger than the width of corresponding macro traces at contact regions of a subassembly film.

In some instances, the electrical contacts/traces at subassembly connection sites on the base layer are preferably formed on the upper surface of the base layer. In those instances, the electrical contacts/traces on the base layer may contact the lower surface of the subassembly film when the first subassembly is placed on the base layer and/or joined to the base layer.

Joining of the base layer to the first subassembly may occur by contacting the first subassembly with the base layer such that the lower surface of the subassembly film (i.e., the side not bearing a die) contacts the upper surface of the base layer. The base layer and first subassembly may then be bound, e.g., with mechanical fasteners, an adhesive, conductive material, application of heat, application of pressure, or a combination thereof. In some embodiments, the first subassembly and base layer are joined via a lamination process, in which the base layer is brought into contact with the lower surface of the subassembly film, and heat and/or pressure are applied to join the subassembly film to the base layer. Without limitation, the subassembly film and base layer are preferably joined such that one or more electrical contacts/traces (or regions thereof) on the subassembly film overlap with corresponding electrical contacts/traces at a subassembly connection site of the base layer.

Like the subassembly films, the base layers described herein may be configured to soften and/or become tacky upon the application of heat. For example, the base layers may be configured to soften when exposed to heating conditions that are the same or similar to those specified above for the subassembly films. Softening/tackifying of the base layer may facilitate its adherence and/or bonding to a subassembly film.

The terms “cover film” and “coverlay” are used interchangeably herein to refer to one or more films that may be applied over at least one of the subassembly film, die, and base layer. Similar to the subassembly films and the base layers, the cover films described herein may be manufactured from any suitable material. As non-limiting examples of such materials, mention is made of the materials specified above as suitable for use as the subassembly film. Without limitation, the cover films described herein are preferably formed from a film, including of PET, PI, PEN and other flexible material types. In some embodiments the cover films and subassembly films are formed from the same material, e.g., PET.

Like the subassembly film and base layer, the cover film may be configured to soften and/or become tacky upon the application of heat. For example, the cover film may be configured to soften when exposed to heating conditions that are the same or similar to those specified above for the subassembly film and/or base layers. Softening/tackifying of the cover film may facilitate its adherence and/or bonding to a subassembly film.

The cover film may be joined to a first subassembly and/or base layer in any suitable manner. For example, the cover film may be contacted with the side of a first subassembly bearing a die, e.g., the upper surface of the subassembly film. The cover film and first subassembly may then be joined, e.g., with an adhesive, a mechanical fastener, application of heat, application of pressure, or a combination thereof. In some embodiments, the cover film is joined with a first subassembly via a lamination process, in which a cover film and the first subassembly are brought into contact and heat and/or pressure are applied to join the cover film to the upper surface of a subassembly film and/or other components thereon.

Although not required, the cover film may include one or more openings that may extend through its entire thickness. Such opening(s) may have any desired shape, such as square, rectangular, pentagonal, hexagonal, circular, or another geometric or irregular shape. In some embodiments, the cover film includes an opening that has substantially the same shape as the exterior geometry of a die in a first subassembly. In such instances, the cover film may be positioned on and/or joined to the first subassembly such that the opening frames the die. Of course, such embodiment is exemplary only, and the cover film may include one or more openings having a shape that differs from the exterior geometry of a die. For example, a die may have a quadrilateral exterior geometry (e.g., it may be square, rectangular, etc.) and the openings in the cover film may be circular or another non-quadrilateral shape.

The subassembly film may have a thickness that is greater than the thickness of a die placed on a subassembly film. In such instances, the opening in the subassembly film may form a recess in conjunction with a top surface of a die when the subassembly film is applied. Such recess may be filled or remain unfilled.

In instances where the die is a LED die, the upper surface of the LED die may be configured to emit light. The recess defined by the upper surface of the LED die and the opening in the cover film may be filled with a material that converts light emitted by the LED die (i.e., primary light), to light of another wavelength and/or wavelength range (i.e., secondary light). Such materials are hereinafter referred to as “conversion material.” The conversion material may be placed in contact with the LED die, so as to form a chip/die level conversion structure. The conversion material could be totally encapsulating the LED die on all sides, or in contact with just one surface. Alternatively, the conversion material may be separated from the upper surface of the LED die, e.g., by a transparent spacing material. Such configuration may be understood to be a remote conversion configuration. Preferably, the conversion material is a cerium-activated yttrium aluminum garnet, e.g., Y₃Al₅O₁₂:Ce (YAG:Ce).

The present disclosure will now proceed to describe exemplary methods of manufacturing electronic assemblies using subassembly films. For the purpose of clarity and ease of understanding, the present disclosure will focus on methods in which a first subassembly including a single die is formed, and subsequently joined to a base layer that includes a single subassembly connection site. It should be understood that such description is exemplary only, and that the principles of the described methods may be used to form more complex electronic assemblies. Indeed, the present disclosure envisions methods in which a base layer includes a plurality (e.g., 2, 3, 5, 10, 20, 50, 100, 1000, etc.) of subassembly connection sites, and a corresponding plurality of first subassemblies are joined to such sites. Likewise, the present disclosure envisions embodiments wherein one or more first subassemblies are joined to a first base film to form a second subassembly, and a plurality of second subassemblies are joined to form an electronic assembly such as but not limited to a lighting panel.

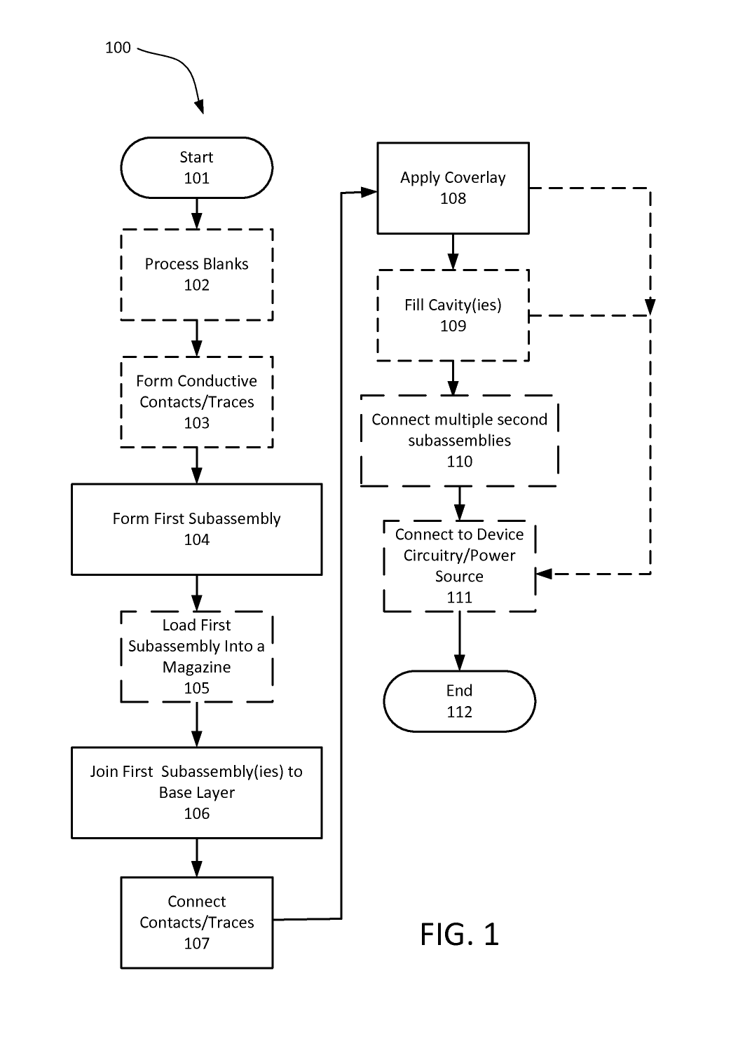

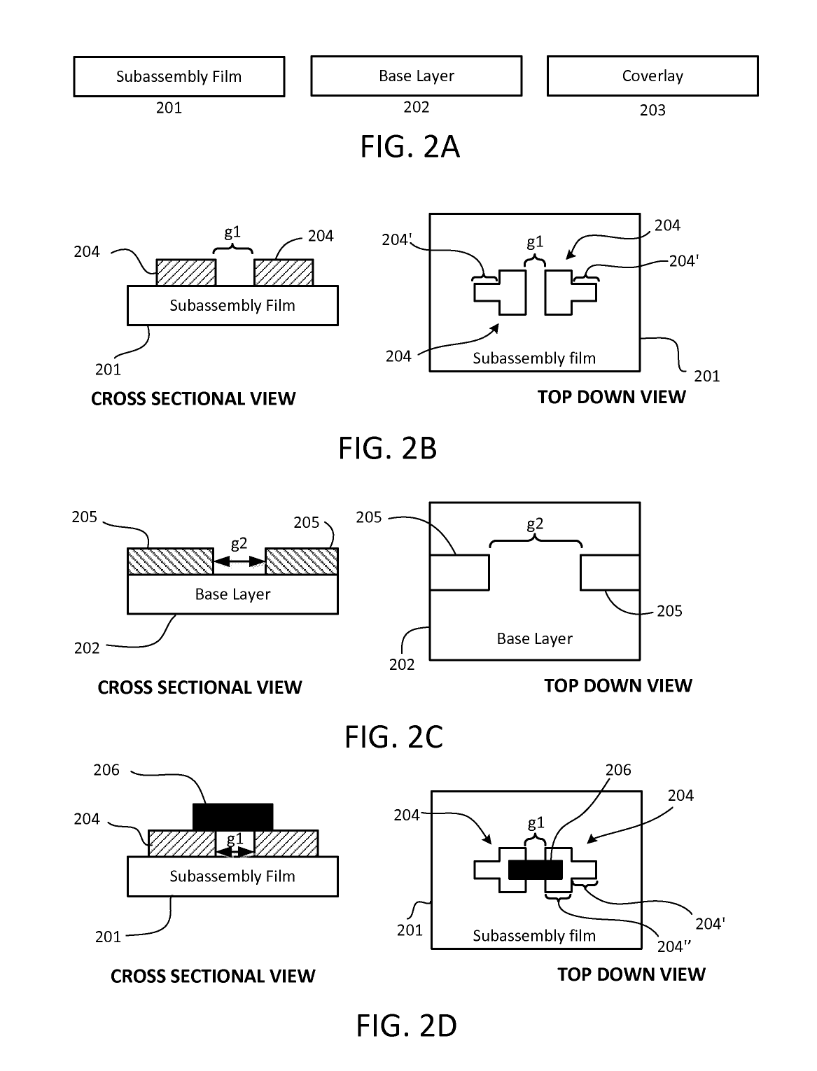

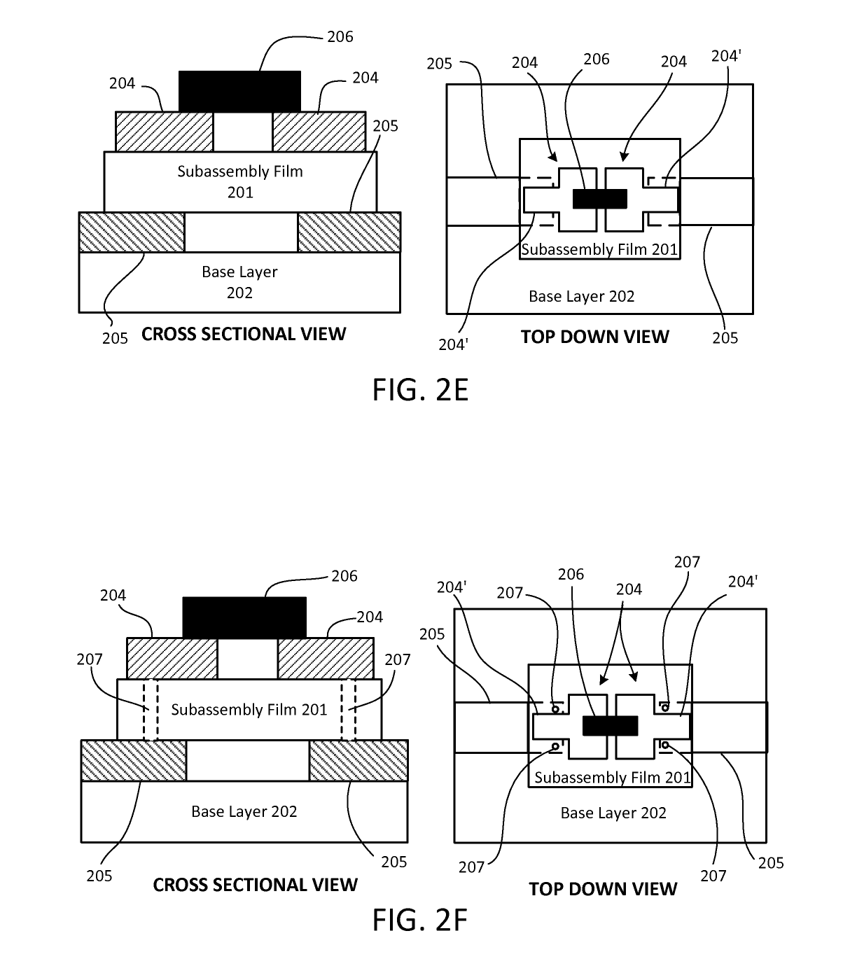

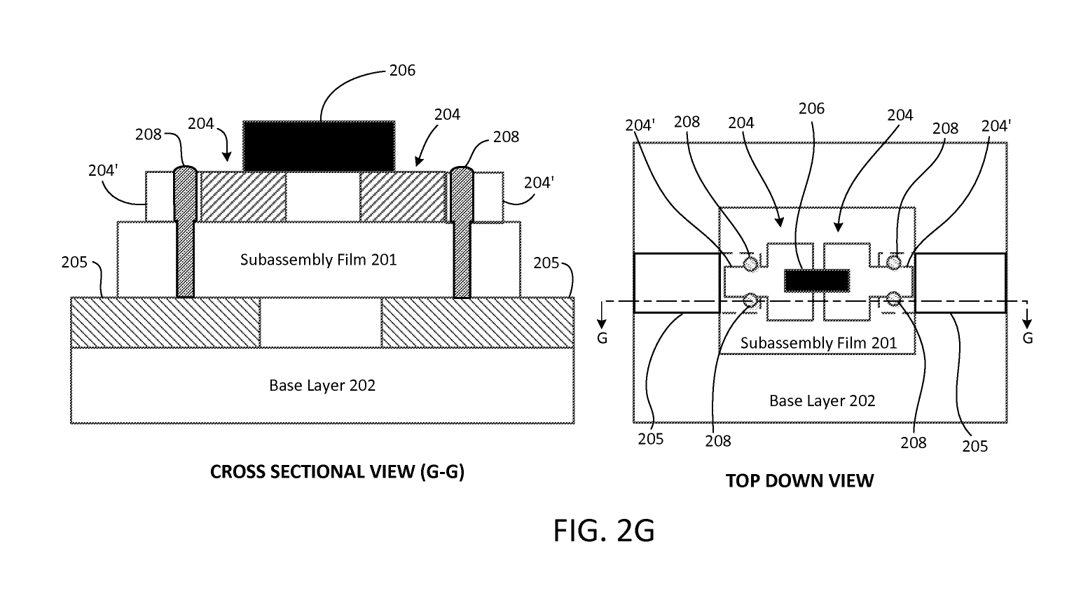

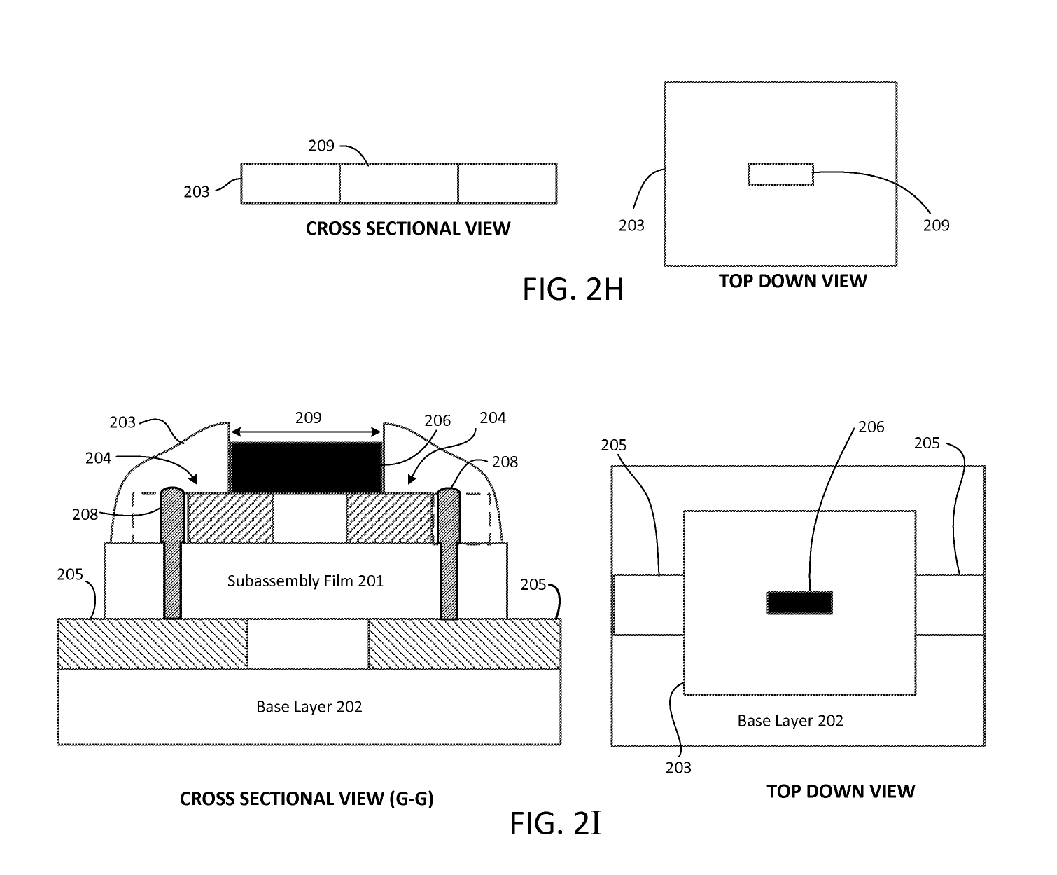

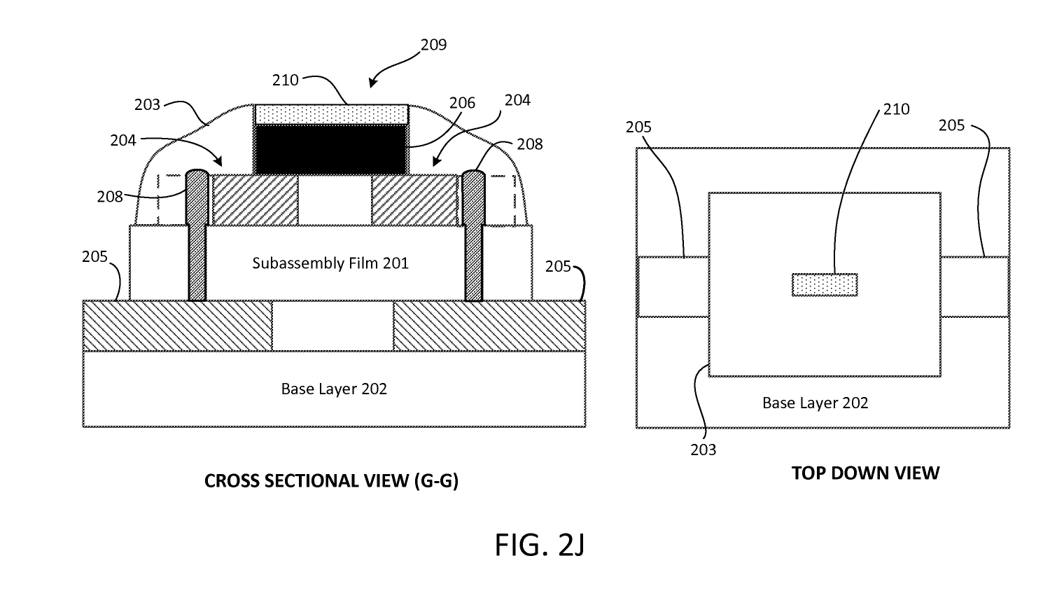

Reference is now made to FIG. 1, which depicts a flow diagram of an exemplary method in accordance with the present disclosure. As shown, method 100 begins at block 101. The method may then proceed to optional block 102, wherein stock subassembly films, base layers, and cover films are processed into corresponding blanks. For example, the stock subassembly films, base layers, and cover films may be cut to appropriate dimensions, subject to one or more pre-treatment processes, combinations thereof, and the like. This concept is illustrated in FIG. 2A, wherein a blank subassembly film 201, base layer 202, and cover film 203 are illustrated.

Optional block 102 is not necessary, and may be omitted, e.g., when blank subassembly films, base layers, and/or cover films are already available. Once blank subassembly film(s), base layer(s), and cover film(s) are available, the method may proceed to optional block 103, wherein conductive contacts/traces may be formed on the upper and/or lower surfaces of the blank subassembly and blank base layers. Without limitation, such contacts/traces are preferably formed on the upper surface of the blank subassembly film and base layers. This concept is illustrated in FIGS. 2B and 2C, which depict conductive contacts/traces 204, 205 formed on the upper surfaces of subassembly film 201 and base layer 202, respectively.

The contacts/traces on the subassembly film and base layer may be formed from any suitably conductive material, such as aluminum, copper, nickel, gold, silver, silver-filled epoxy, gold/nickel plated aluminum, gold/nickel plated copper, gold/nickel plated silver, combinations thereof, and the like. Without limitation, the conductive contacts/traces are preferably formed from copper, silver-filled epoxy, conductive ink, gold, and combinations thereof.

The conductive contacts/traces may be formed on a blank subassembly film and blank base layer using any suitable technique. For example, conductive contacts/traces may be formed by electroless deposition, electrolytic deposition, dip coating, printing, stamping, thin-film deposition, sputtering, etching, combinations thereof and the like. In some embodiments, conductive material may be deposited in such a way as to form contacts/traces having a desired configuration. Alternatively or additionally, a layer of conductive material may be deposited on the surface of the blank subassembly and base layers, and subsequently processed (e.g., via etching) to form contacts/traces of a desired configuration.

As noted previously, the contacts/traces on the subassembly film may be configured so as to define a placement location of a die, which may be in the form of a gap between two contacts/traces on the subassembly film. This concept is illustrate in FIG. 2B, wherein gap g1 is present between two contacts/traces 204 formed an upper surface of subassembly film 201. The width of gap g1 and the geometry of contacts/traces 204 adjacent to gap g1 may be configured to compliment the spacing and configuration of bond pads (not shown) on a die that is to be placed on such gap. Thus for example, a die to be placed at gap g1 may include bond pads that are separated by a uniform distance, such as less than or equal to about 60 to about 150 microns. In such instances, the width of gap g1 and the dimensions of contacts/traces 204 may be controlled such that the bond pads of the die make electrical contact with respectively contacts/traces 204. In some embodiments, gap g1 has a width ranging from about 10 microns to about 1000 microns, such as about 25 to about 500 microns, about 50 to about 250 microns, about 50 to about 150 microns, or even about 50 to about 100 microns. Of course, such ranges are exemplary only, and any suitable gap size may be used for gap g1. Without limitation, the width of gap g1 is preferably selected so as to enable contact between contacts/traces 204 on either size of the gap with corresponding contacts on a die that will be placed on the gap.

Similarly the size of contacts/traces 204 on either side of gap g1 may be selected so as to enable sufficient contact with bond pads on a die. In some embodiments, contacts/traces 204 on either side of gap g1 may be 1-20 times (e.g., about 1 to about 15, about 1 to about 10, or even about 1 to about 5) as large as the corresponding bond pads of a die.

Contacts/traces 205 on base layer 202 may define one or more subassembly connection sites (not labeled). Such subassembly connection sites may be delineated by one or more gaps g2 defined by contacts/traces 205. The width of gap g2 and the configuration of contacts/traces 205 on either side of gap g2 may correspond with the placement and configuration of contacts/traces 204 of subassembly film 201. That is, the width of gap g2 may be selected such that at least a portion of contacts/traces 205 overlap with at least a portion of contacts/traces 204 when subassembly film 201 and base layer 202 are overlaid. Without limitation, gap g2 is preferably slightly (˜e.g., about 1 to about 25%) larger than gap g1. In such instances, die shorting may be lowered, minimized, or eliminated.

In some embodiments, contacts/traces 204 may include one or more regions 204′ that extend from portions of contacts/traces 204 adjacent to gap g1. Such regions 204′ may at least partially overlap with contacts/traces 205 at a subassembly connection site (not labeled) of base film 202 when subassembly film 201 and base layer 202 are overlaid, or vice versa. This concept is illustrated in the cross sectional and top down view of FIGS. 2E and 2F, which illustrate regions 204′ of contacts/traces 204 as overlapping with a portion of contacts/traces 205 on base layer 202. Such regions 204′ may facilitate the electrical connection of contacts/traces 204 with contacts/traces 205.

In some embodiments, contacts/traces 204 on subassembly film 201 may be configured to define a die placement location for a microelectronic die, such as a bare LED die.

The size of such microelectronic die may range from greater than 0 to about 1500 square microns, such as about 50 to about 1000 square microns, about 100 to about 800 square microns, about 200 to about 700 square microns, about 250 to about 650 square microns, about 300 to about 600 square microns, about 400 to about 500 square microns, or even about square 500 microns. In such instances, the die placement location may include a gap g1 that is sized such that contacts/traces on either side of it contact corresponding bond pads when the microelectronic die is placed on the die placement location, e.g., across gap g1.

As noted in the background, it can be difficult to place small dies (such as a microelectronic die) on a small die placement location using conventional pick-and-place methodology. Indeed if such technology is used, costly and time consuming manual inspection of the placed microelectronic dies may be needed. In some embodiments, the present disclosure addresses this issue by forming die placement locations on a subassembly film using a combination of macro traces and micro traces.

Accordingly, in some embodiments a gap for the placement of a microelectronics die (e.g., a bare LED die) is formed on a subassembly film using micro traces and one or more regions for connecting to corresponding contacts/traces on a base film are formed by macro traces extending from the micro traces defining the gap. For example, regions 204′ of contacts/traces 204 may be macro traces, whereas region 204″ of contacts/traces 204 (e.g., adjacent to gap g1) may be micro traces.

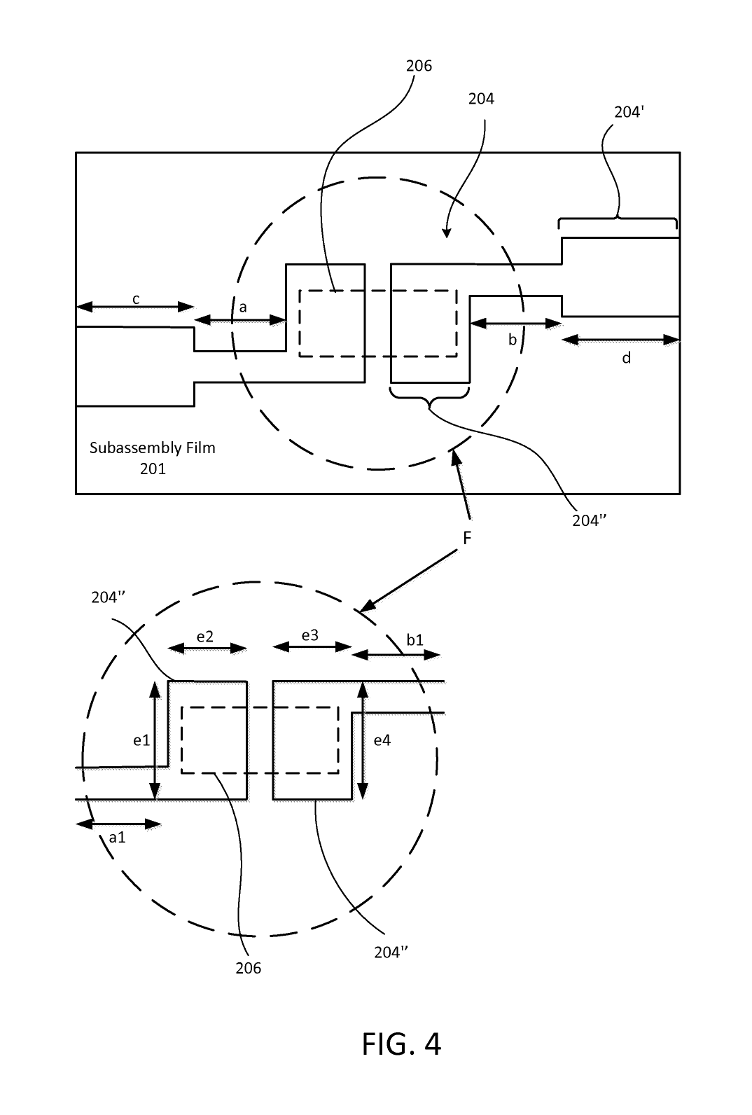

To further illustrate this concept, reference is made to FIG. 4, which depicts a top down view of an exemplary configuration of contacts/traces 204 on subassembly film 201. As shown in the illustrated embodiment, subassembly film 201 may include contacts/traces 204 that include segments a, b c, and d. Segments a and b may be formed by micro traces, whereas regions c and d may be formed by macro traces. In such instances, the macro traces at segments c and d may have a line width greater than the line width of the micro traces in regions a and b, respectively. For example, the macro traces in regions c and d may have a line width ranging from 100 microns to about 250 microns, such as 100 microns to about 200 microns, 100 microns to about 150 microns, or even 100 microns to about 125 microns. In contrast, the micro traces in regions a and b may have a line width less than 100 microns, such as greater than 0 to less than 100 microns, about 30 microns to about 75 microns, about 50 microns to about 75 microns, or even about 60 to about 75 microns. Alternatively or additionally, the macro traces in regions c and d may be 1-3 times larger/thicker than the micro traces in regions a and b. In any case, macro traces in regions c and d may define regions (e.g., regions 204′ in FIGS. 2A, 2D, and 2D) that will at least partially overlap with contacts/traces at a subassembly connection site on a base film.

In addition to micro and macro traces, contacts/traces 204 may define regions 204″ for contacting a die. This concept is illustrated in FIGS. 2D and 4, wherein two regions 204″ are depicted in area F. For the sake of clarity, regions 204″ are illustrated as having a generally rectangular shape. In the case of the embodiment of FIG. 4, such regions are illustrated as having a rectangular shape defined by dimensions e1 and e2, and e3 and e4, respectively. It should be understood that the illustrated geometry of regions 204″ is exemplary only, and that such areas may have any suitable configuration. Without limitation, the geometry and/or dimensions of regions 204″ are selected to correspond to the geometry and dimension of bond pads (not shown) on die 206. Accordingly, dimensions e1, e2, e3, and e4 may vary depending on the configuration and placement of bond pads on die 206.

As will be described later in connection with block 104, the use of a combination of macro and micro traces to define die placement locations using contacts/traces 204 may facilitate accurate, rapid, and/or facile placement of microelectronic dies at such locations. For example, subassembly films including such contacts/traces may be brought into close proximity with pick-and-place and/or other die placement machinery. As a result, accurate placement of a die at a die placement location (e.g., across a gap defined by micro traces and/or regions 204″) may occur, potentially without the need for manual inspection. Moreover, the use of macro traces to define a gap for the placement of a die increases the area of the contacts/traces on either side of the gap. Such area may be 1 to 5 times (e.g., three times) the width of the die that will be placed across the gap. As a result, it may be possible to reposition (i.e., rework) the die on the gap one, two or more times, in the event that erroneous placement of the die occurs.

The contacts/traces 205 of base layer 202 may be macro traces that have a line width that is greater than or equal to the line width of the macro traces forming regions 204′. This concept is illustrated in FIG. 2E, wherein contacts/traces 205 are depicted as having a width that is larger than that of contacts/traces 204 in regions 204′. Without limitation, macro traces forming contacts/traces 205 at a subassembly connection site are preferably greater than or equal to about 10%, 20%, 30%, 40%, 50%, 100%, 150%, 200%, 250%, or even about 300% wider than the contacts/traces forming region 204′ of contacts/traces 204. Thus for example, contacts/traces 204 in region 204′ may have a line width of about 100 to about 225 microns. In such instances, contacts/traces 205 at a subassembly connection site on base film 202 may have a line width of about 110 to about 675 microns.

As will be described later, a subassembly containing the subassembly film may be placed on a base film, such that traces/contacts on the subassembly film overlap at least a portion of the traces/contacts on the base film. In such instances, the use of macro traces on a base film (particularly with line widths exceeding the line width of contacts/traces in region 204′) may facilitate such placement. Indeed, the use macro traces with relatively large line widths may increase the area over which the subassembly film may be suitably placed. As a result, it may be possible to use less sophisticated processes/machinery to place a subassembly film (or a subassembly containing such a film) on a base film.

Returning to FIG. 1, it is noted that optional block 103 is not required, particularly when subassembly films and base layers that include electrical contacts/traces of a desired configuration are available, e.g., from a vendor or another source. In any case, once such films are available, the method may proceed to block 104, wherein a first subassembly is formed. Formation of the first subassembly may be accomplished by placing and optionally joining a die on/to a subassembly film at an appropriate location. This concept is illustrated in FIG. 2D, wherein die 206 is illustrated as placed on electrical contacts/traces 204 such that bond pads (not shown) on die 206 contact contacts/traces 204 on either side of gap g1. This concept is also illustrated in FIG. 4, wherein die 206 is depicted as contacting regions 204″ of contacts/traces 204. In either instance, die 206 may be electrically connected to contacts/traces 204.

Die 206 may be placed across gap g1 in any suitable manner, including manually, mechanically, and combinations thereof. Without limitation, die 206 may be placed across gap g1 mechanically, e.g., using a pick-and-place system or other machinery. Generally, such systems may place a die using a direct chip attach methodology using a pick up head and a subassembly film positioning system (e.g., a wafer positioning system), either or both of which may translate in an X and Y dimension. The pick up head may pick up a die from a source of dies, and travel to a die placement site (e.g., a gap g1 on subassembly film 201) on the subassembly film. The placement site may then be confirmed by the pick-and-place system, e.g., using a pattern recognition system. Once the die placement location is confirmed, the pick up head may deposit the die at the die placement site with a desired orientation and pad alignment.

With the foregoing in mind, the size of the subassembly film may impact placement accuracy. Accordingly, the size of the subassembly film may be selected so as to facilitate the accurate placement of dies on a subassembly film. In particular, the size of subassembly film 201 may be selected so as to reduce or minimize the distance a pick up head must travel before it reaches a die placement location, e.g., a gap g1 on subassembly film 201.

Thus for example subassembly film 201 may have a size ranging from about 10 mm² to about 150 mm², such as about 10 mm² to about 100 mm², about 10 mm² to about 70 mm², or even about 10 mm² to about 50 mm². In some embodiments, subassembly film 201 has a size of about 10 mm², 20 mm², 30 mm², 40 mm², 50 mm², 60 mm², or even about 70 mm². Regardless of the size, subassembly film 201 and a die pick up head of a pick-and-place machine may be located relative to one another such that the distance the pick up head needs to move is relatively small before it reaches a die placement location on subassembly film 201. In some embodiments, the pick up head and subassembly film are located relative to one another such that a pick up head needs to move less than about 2 cm, such as less than or equal to about 1.5 cm, less than or equal to about 1 cm, or even less than or equal to about 0.5 cm before it reaches a die placement location on subassembly film 201.

As noted previously, gap g1 may be defined by contacts/traces that are macro traces, micro traces, or a combination thereof. By limiting the distance between a source of dies and a gap g1, placement of a die across gap g1 may be rapidly and accurately performed with machinery (e.g., a pick-and-place system). This may be true even if a die to be placed is small (e.g., a microelectronic die, and/or if the die placement location (e.g., a gap) is defined by small contacts/traces such as micro traces. As a result, placement of die 206 may be accomplished mechanically and, potentially, without the need for manual inspection. Without limitation, die 206 is preferably a microelectronic die that is placed on a die placement location defined by gap g1 using a pick-and-place system.

Of course, mechanical placement of dies is exemplary only, and is not required. Indeed, the present disclosure envisions embodiments wherein dies are manually place across gap g1. Moreover, while the present disclosure envisions methods in which pre-formed dies are placed across gap(s) g1, the use of pre-formed dies is not required. Indeed, the present disclosure envisions methods wherein a die 206 is formed across gap g1, e.g., via photo printing, three dimensional (3D) printing, self-assembly, other forms of deposition, combinations thereof, and the like.

Once a die 206 has been placed at a die placement location (e.g., across gap g1), it may be joined to subassembly film 201 via any suitable mechanism. For example, subassembly film 201 may be heated and/or pressurized until it partially melts, becomes tacky, or a combination thereof. At that point, subassembly film 202 may stick to or otherwise physically retain die 206. Alternatively or additionally, die 206 may be bonded to subassembly film 201 using a suitable adhesive and/or connective agent, such as a solder, a conductive paste, or a combination thereof. Without limitation, die 206 is preferably bonded to subassembly film 201 using a conductive paste, such as the CP-300 interconnection paste available from Hitachi Chemical, or the DB-1590 die attach material available commercially from ECM Company, or the ECCOBOND S-3869 available from Henkel, or ABLEBOND® 84-1LMI available from Ablestik, or similar die-attach materials. In some embodiments, die 206 may be initially bonded to subassembly film using a conductive paste or solder (e.g., CP-300), followed by a solder reflow process and/or additional thermal treatment.

As may be appreciated, blocks 101-104 may be repeated to form numerous subassemblies from a plurality of subassembly films and electronic dies, which may be immediately subject to additional processing or stored. In this regard, the method may proceed to optional block 105, wherein first subassemblies may be loaded into a magazine or other storage device. In some embodiments, the magazine may be configured for use by machinery that will place one or more first subassemblies on a base film. Non-limiting examples of such machinery include electronic die placement machines such as a chip (die) shooter, a pick-and-place system, combinations thereof, and the like.

Whether or not first subassemblies are stored and/or loaded into a magazine, the method may proceed to block 106, wherein at least one first subassembly is joined to a base layer. This concept is illustrated in FIG. 2E, wherein a first subassembly (not labeled) including subassembly film 201 bearing die 206 on contacts/traces 204 is depicted overlying base layer 202 and contacts/traces 205 formed thereon.

In this regard, joining of the base film 202 and the first subassembly may begin by bringing the bottom surface of subassembly film 201 into contact with the top surface of base layer 202, such that contacts/traces 204 of subassembly film 201 at least partially overlie contacts/traces 205 of base layer 202. This concept is illustrated in the top-down view in FIG. 2E and as shown in the top down view of FIGS. 2E-2G, wherein regions 204′ of contacts/traces 204 are illustrated as overlapping a portion of contacts/traces 205. Base film 202 and the upper surface of subassembly film 201 may be brought into contact in any suitable manner. For example, a first subassembly including subassembly film 201 may be deposited on the upper surface of base film 201, e.g., using a pick-and-place machine, a die shooter, combinations thereof, and the like.

By way of example, one or more first subassemblies may be available in a magazine of a placement device. At this point, one or more pick up heads of the placement device (e.g., attached to one or more spindles) may retrieve a first subassembly from the magazine. The pick up head(s) may make contact with a subassembly film of the first subassembly at a location away from the die placement location. Alternatively or additionally, a single suction cup may be used pick a first subassembly over the die placement location, with or without contacting the die.

The contacts/traces at region 204′ of the subassembly may then be aligned with corresponding contacts/traces 205 on the base layer 202, which may be provided using a base layer handling system. For example, the contacts/traces at region 204′ may have a center point, which may be aligned with a corresponding point on contacts/traces 205. The X-Y alignment of contacts/traces at region 204 with contacts/traces 205 may be managed by the subassembly placement device (e.g., a chip shooter or other pick-and-place machine). In some embodiments, patterns or other features of the first subassembly may be utilized by the placement device to enhance alignment and positioning of the first subassembly (or, more particularly, subassembly film 201) over the base layer 202.

In any case, the base layer may be pre-heated to facilitate bonding of the first subassembly. For example, the base layer may be heated to about 70 to 90° C. At such temperature, contact of the base layer 202 with the subassembly film 201 may result in complete or partial melting of subassembly film 201 and or an adhesive thereon, resulting in adherence of subassembly film 201 (and hence, a first subassembly) to base layer 202. Once a desired number of first subassemblies are placed on base layer 202, the base layer 202 handling system may advance to and present another base layer, and the process may repeat.

As noted previously contacts/traces 205 on base film 202 may define subassembly connection sites using macro traces that have a line width that is greater than the line width of contacts/traces 204 on subassembly film 201 in region 204′. In such instances, the macro traces at a subassembly connection site on the base film may define a contact area that is relatively large, as compared to the are defined by region 204′ of contacts/traces 204. As a result, it may be possible to use a process and/or placement system having relatively low sensitivity and/or accuracy to place a first subassembly on base film 201 such that contacts/traces 204 overlap with contacts/traces 205. For example, a first subassembly may be suitably placed on a base film manually or mechanically, e.g., using a die shooter, a pick-and-place machine, combinations thereof, and the like.

Once subassembly film 201 and base layer 202 are overlaid in this manner, they may be joined in any suitable fashion. For example, base layer 202 and subassembly film 201 may be joined through the application of heat and/or pressure, via an adhesive, via a mechanical fastener, or a combination thereof. In some embodiments, base layer 202 and subassembly film 201 may be joined via the application of heat and/or pressure. For example, subsequent to contacting subassembly film 201, base layer 202 may be heated to a temperature that causes subassembly film 201 and/or an adhesive layer thereon to partially melt and/or become tacky. For example, subassembly film 201 may be heated to a temperature ranging from about 60 to about 150° C., such as about 60 to about 130° C., about 60 to about 100° C., or even about 60 to about 90° C. Of course, such temperature may depend on the material properties of subassembly film 201 and/or an adhesive thereon and thus, base layer 202 may be heated to any suitable temperature. In any case, melting and/or tackification of subassembly film 201 or an adhesive thereon may cause subassembly film 201 and/or an adhesive thereon to physically and/or chemically bond to base film 202.

Of course, it is not necessary to wait until subassembly film 201 (or an adhesive thereon) and base layer 202 are in contact to heat base layer 202 as described above. Indeed, the present disclosure envisions embodiments wherein prior to contacting subassembly film 201, base layer 202 is pre-heated to a temperature that will cause subassembly film 201 and/or an adhesive thereon to partially melt and/or become tacky, such as the temperature ranges noted above. Upon contacting pre-heated base layer 202, subassembly film 201 and/or an adhesive thereon may then melt and/or become tacky. This may cause subassembly film 201 and/or an adhesive thereon to physically and/or chemically bond to base layer 202. In this way, placement and joining of subassembly film 201 onto base layer 202 may be accomplished in a single step.

After subassembly film 201 is joined to base layer 202, the resultant combination of subassembly film 201 (optionally including an adhesive), base layer 202, die 206, and contacts/traces 204, 205 may be subject to an additional heating process to enhance the bond between such components. For example, the combination of base layer 202, subassembly film 201, optional adhesive, die 206, and contacts/traces 204, 205 may be heated at approximately 60 to 90° C. for about 1 to about 4 minutes. Such additional heating process may cause subassembly film 201 and/or an adhesive thereon to further soften and/or melt, which may enhance the bond between subassembly film 201 and/or an adhesive thereon with base film 202, and may cause subassembly film 201 to substantially conform to the upper surface of base film 202. This may also enhance retention of die 206 on contacts/traces 204, e.g., by causing die 206 to sink or otherwise embed within subassembly layer 201.

The joining of subassembly film 201 with a base layer 202 may be facilitated by the application of pressure. For example, base layer 202 and subassembly film 201 may be subject to elevated pressure when subassembly film 201 is partially melted and/or tackified. For example, the base film 202 and a partially melted and/or tackified subassembly film 201 may be subject to calendaring or other pressure treatment, e.g., at a pressure ranging from greater than or equal to about 5 kgf/cm² to about 100 kgf/cm², including any and all pressures therein.

Base layer 202 and subassembly film 201 may also be joined/bonded using an adhesive and/or a fastener. For example an adhesive (not shown) may be applied to the lower surface of subassembly film 201, an upper surface of base layer 202, or a combination thereof. Such adhesive may bond subassembly film 201 with base layer 202 when the upper surface of base layer 202 is brought into contact with the lower surface of subassembly film 201. Alternatively or additionally, one or more holes (not shown) may be formed through subassembly film 201 and into or through base layer 202. Such hole(s) may then be filled with an adhesive (e.g., an epoxy or other bonding agent), thus bonding subassembly film 201 to base layer 202. In this way, an adhesive and/or mechanical fastener may be used to join subassembly film 201 to base layer 202.

Joining/bonding of the first subassembly and base layer 202 may fix die 206 and contacts/traces 204 at an appropriate position, relative to contacts/traces 205. In particular, joining/bonding of the first subassembly to base film 202 may fix contacts/traces 204 at a position relative to contacts/traces 205, such that at least a portion of contacts/traces 204 overlap a portion of contacts/traces 205. This concept is illustrated the top down view in FIG. 2E, which depicts region 204′ of contacts/traces 204 overlying a portion of contacts/traces 205 of base layer 202.

The method may then proceed to block 107, wherein the electrical contacts/traces on the subassembly film are connected to electrical contacts/traces on the base film. Such contacts/traces may be connected in any suitable manner, e.g., with one or more wires, conductive material (e.g. applied as solder points, in vias, etc.), combinations thereof, and the like. Without limitation, contacts/traces on the subassembly film are preferably connected to contacts/traces on the base film by forming one or more vias through the subassembly film, and filling such vias with conductive material so as to electrically connect contacts/traces 204 with contacts/traces 205.

One example of this concept is illustrated in FIGS. 2F and 2G. As shown in the cross-sectional view in FIG. 2F, vias 207 may be formed through the thickness of subassembly film 201. In this case, cylindrical vias 207 are illustrated as formed in a region of subassembly film 201 that is proximate to regions 204′ of contacts/traces 204. It should be understood that such illustration is exemplary only, and that any number of vias 207 may be formed at any suitable location within subassembly film 201. This is exemplified by the top down view in FIG. 2F, which illustrates four vias 207. Moreover, it should be understood that vias 207 may have any suitable geometry, and that cylindrical vias are not required.

Regardless of their number and/or configuration, vias 207 may be formed through the entire thickness of subassembly film 201. This concept is illustrated in FIG. 2F, wherein each via 207 extends from the upper surface to the lower surface of subassembly film 201. In this way, each via 207 may form a channel or passage through subassembly film 201. Without limitation, vias 207 are preferably formed such that they extend through the entire thickness of subassembly film 201, so as to expose a portion of contacts/traces 205 on underlying base layer 202. This is illustrated in FIG. 2F, wherein vias 207 expose a portion of contacts/traces 205 in contact with a bottom surface of subassembly film 201.

Vias 207 may be formed in any suitable manner. For example, vias 207 may be formed by mechanical drilling, laser drilling, etching, ablating, or otherwise removing material from a desired region of subassembly 201. Without limitation, vias 207 are preferably formed by laser drilling.

After vias 207 are formed, they may be filled with conductive material so as to electrically connect contacts/traces 204 with contacts/traces 205. This concept is illustrated in FIG. 2G, which depicts vias 207 as filled with conductive material 208. As shown, conductive material 208 contacts the exposed portion of contacts/traces 205 through vias 207, and also contacts a portion of contacts/traces 204. In this way, conductive material 208 may electrically connect contacts/traces 204 with contacts/traces 205. The cross sectional view in FIG. 2G is taken along line G-G which intersects a pair of vias filled with conductive material 208 on one side of subassembly film 201. Similar cross sectional views are provided in FIGS. 2I and 2J.

Any suitable conductive material may be used to electrically connect contacts/traces 204 with contacts/traces 205. As non-limiting examples of suitable conductive materials, mention is made of metals such as aluminum, copper, gold, nickel, silver, and the like, conductive solder, conductive ink, conductive paste, and conductive polymers. Without limitation, conductive material 208 is preferably formed from the CP-300 conductive interconnect paste available from Hitachi Chemical or the DB-1590 conductive adhesive available from ECM Company.

The method may then proceed to block 108, wherein at least one a coverlay is applied to the first subassembly. In this regard, the coverlay may be sized so as to cover all or a portion of the first subassembly. For example, the coverlay may be sized to cover all or a portion of the subassembly film, contacts/traces formed thereon, a die joined thereto, and combinations thereof.

In some embodiments, at least one opening may be formed in the coverlay. Such opening(s) may correspond to at least one die in a first subassembly attached to a base film. That is, such opening(s) may be formed in the coverlay at a location that corresponds to the location of a die (or dies) on a first subassembly joined to a base film. Such opening(s) may also have the same or different geometry as their corresponding die. For example, if a die is in the shape of a rectangle, an opening in the coverlay may have a rectangular or other shape. Without limitation, the opening(s) in the coverlay preferably have the same geometry as a die in a first subassembly attached to a base film. In such instances, the coverlay may be joined to the first subassembly such that an opening in the coverlay “frames” or otherwise surrounds a die, but leaves an upper surface of the die exposed.

This concept is illustrated in FIGS. 2H and 2I. As shown in FIG. 2H, at least one opening 209 may be formed in coverlay 203. In this instance, a single opening having a rectangular geometry is illustrated for the sake of convenience and ease of understanding. As shown in FIG. 2I, coverlay 203 including opening 209 may be contacted with and joined to a first subassembly on base film 202. For example, coverlay 203 may be positioned on the first subassembly such that opening 209 frames or otherwise surrounds at least a portion of die 206 on subassembly film 201. Coverlay 203 may then be joined to subassembly film 201 and/or other portions of the first subassembly.

Coverlay 203 and the first subassembly may be joined in any suitable manner, such as with the application of heat, pressure, light, an adhesive, a mechanical fastener, combinations thereof, and the like. Without limitation, coverlay 203 is preferably configured to soften and/or tackify when exposed to heat. For example, coverlay 203 may soften or tackify when exposed to heat at a temperature ranging from about 50 to about 150° C., such as about 60 to about 125° C., about 75 to about 110° C., about 80 to about 100° C., or even about 85 to about 95° C. Heat may be applied for any suitable time period, such as about 0.5 to about 10 minutes, about 1 to about 5 minutes, about 1 to about 3 minutes, or even about 1 to about 2 minutes. Without limitation, coverlay 203 is preferably exposed to heat at a temperature ranging from about 85 to about 95° C. for about 1 to about 2 minutes.

Softening and/or tackification of coverlay 203 may cause it to physically or chemically bond to portions of the first subassembly with which it is in contact. For example, coverlay 203 may physically or chemically bond to all or a portion of die 206, conductive material 208, traces/contacts 204, subassembly film 201, traces/contacts 205, and/or base film 202. In some embodiments, coverlay 203 may substantially conform to surfaces of the first subassembly when it is joined to the first subassembly as described above. This concept is illustrated in FIG. 2I, wherein coverlay 203 is depicted as conforming to the side surfaces of die 206, the upper surface of conductive material 208, a portion of the upper surface of contacts/traces 204, and a portion of the upper surface of subassembly film 201.

After the softened/tackified coverlay 203 is joined to the first subassembly, the resultant combination of first subassembly and coverlay 203 may be subject to an additional process to enhance the bond between such components. For example, the combination of first subassembly and coverlay 203 may be heated at approximately 60 to 90° C. for about 1 to about 4 minutes. This additional heating process may cause coverlay 203 to further soften and/or melt, which may enhance the bond between cover layer 203 and upper surfaces of the first subassembly. It may also cause coverlay 203 to substantially conform to the upper surfaces of the first subassembly, as shown in FIG. 2I. Joining coverlay 203 to the first subassembly may further enhance retention of die 206 on contacts/traces 204, e.g., by enveloping or wrapping at least a portion of die 206.

The joining of coverlay 203 to the first subassembly may be facilitated and/or enhanced by the application of pressure. In this regard, the present disclosure envisions embodiments wherein the coverlay is applied to the upper surface of the first subassembly (as bound to a base layer), and subjected to elevated pressure when coverlay 203 is fully or partially melted and/or tackified. For example, a first subassembly bearing a fully or partially melted/tackified coverlay 203 may be subject to calendaring or other pressure treatment, e.g., at a pressure ranging from greater than or equal to about 5 kgf/cm² to about 100 kgf/cm², including any and all pressures therein. In some embodiments, coverlay 203 is applied using one or more of heat and pressure to laminate it to an upper surface of the first subassembly.

Alternatively or additionally, the coverlay 203 may be joined to the first subassembly using an adhesive and/or a fastener. For example, an adhesive (not shown) may be applied to the lower surface of coverlay 203. Such adhesive may bond coverlay 203 to portions of the first subassembly with which it comes into contact, e.g., a portion of die 206, contacts/traces 204, subassembly film 201, conductive material 208, combinations thereof, and the like. Alternatively or additionally, one or more bonding holes (not shown) may be formed through coverlay 203. The hole(s) may then be filled with an adhesive (e.g., an epoxy or other bonding agent), thus bonding coverlay 203 to subassembly film 201, die 206, contacts/traces 204, or a combination thereof.

The coverlay may be configured so as to define a recess above an upper surface of a die. The recess may be formed by the coverlay alone, or it may be defined by the coverlay in conjunction with an upper surface of a die. In the former case, the coverlay may extend over all or a portion of an upper surface of a die, and a recess may be formed above the die, e.g., by stamping, embossing, combinations thereof, or the like. In the latter case, the coverlay may be configured to form a recess in conjunction with the upper surface of a die. For example, the coverlay may have a thickness that exceeds that thickness of the die. Portions of the coverlay surrounding the die (e.g., at a hole in the coverlay) may extend past the height of a side of the die, thus forming one or more sidewalls of a cavity. In such instances, the bottom of the cavity may be defined by all or a portion of the upper surface of the die.

This latter concept is illustrated in FIG. 2I, wherein coverlay 203 is depicted as bound to an upper surface of a first subassembly (which itself is bound to base film 202). As shown, opening 209 within coverlay 203 frames or otherwise borders die 206. In this instance, the bound coverlay 203 has a thickness in a region proximate to opening 209 that is greater than the thickness of the die 206. This is shown in FIG. 2I by the extension of a portion of coverlay 203 above the side of die 206. In this way, coverlay 203 may define the sides of a cavity (not labeled) above die 206, and an upper surface of die 206 may define the bottom of such cavity.

Regardless of how a cavity is formed above a die, its shape may vary widely. For example, the cavities described herein may be cylindrical, conical, or cuboid. Without limitation, the geometry of the cavity preferably corresponds to the geometry of the upper surface of a corresponding die. In any case, the depth of the cavities described herein may range, for example, from about 1 micron to about 1 mm, such as about 10 microns to about 500 microns, about 50 microns to about 250 microns, or even about 100 to about 200 microns. In the case of cylindrical cavities, such cavities may have a diameter ranging from about 0.5 mm to about 5 mm, which may depend on the surface area of the die.

In some embodiments die 206 is a bare light emitting diode die having a surface that emits primary light. In such instances, it may be desirable to convert such primary light to secondary light e.g., with one or more conversion materials, which may be deposited in a cavity formed above the die, as described later in connection with box 109 of FIG. 1 and FIG. 2J. In such instances the geometry and/or depth of a cavity formed above such die may vary based on the desired conversion characteristics, the efficiency of the conversion material, combinations thereof, and the like.

Returning to FIG. 1, the method may then proceed to optional block 109, wherein the cavities formed above one or more dies of the first subassembly may be filled. As noted previously, filling of such cavities may be desired when a die use in a first subassembly is an LED die that emits light from a surface thereof. For example, die 206 in FIGS. 2A-2J may be a bare LED die having an surface that emits primary light. In such instances, it may be desirable to fill a cavity formed above such die with an appropriate material, depending on whether it is desired to convert the primary light emitted by the LED die to light of another wavelength or wavelength range, i.e., secondary light.

If conversion of primary light to secondary light is not desired, a cavity above a die may remain unfilled and the method may proceed to other steps. Alternatively or additionally, such cavity may be filled with a material that is transparent to the primary light emitted by the LED die. Non-limiting examples of such materials include PET, silica, polycarbonate, yttrium aluminum garnet, sapphire, alumina, gallium nitride, other materials transparent to primary light emitted by an LED, combinations thereof, and the like. For the sake of the present disclosure, “transparent to primary light” is used herein to indicate that a material may transmit greater than or equal to about 90% incident primary light emitted from an LED, without conversion.

If the conversion of primary light to secondary light is desired, all or a portion of a cavity formed above an LED die may be filled with a wavelength converting material, i.e., a conversion material. Suitable conversion materials include but are not limited to known phosphors for achieving desired wavelength conversion, such as oxide garnet phosphors and oxynitride phosphors. In some embodiments, all or a portion of a cavity above a die is filled with at least one conversion material selected from cerium-doped garnets such as Lu₃Al₅O₁₂:Ce³⁺, Tb₃Al₅O₁₂:Ce³⁺; nitrides such as M₂Si₅N₈:Eu²⁺, wherein M=Ca, Sr, Ba; oxynitrides such as MSi₂O₂N₂:Eu²⁺, wherein M=Ca, Sr, Ba; and/or silicates such as BaMgSi₄O₁₀:Eu²⁺, M₂SiO₄:Eu²⁺, wherein M=Ca, Ba, Sr. Other suitable conversion materials include or be formed from one or more of the following materials: MAlSiN₃:Eu, MS:Eu, wherein M is a metal selected from Ca, Sr, Ba; A₂O₃:Eu,Bi and A is selected from Sc, Y, La, Gd, Lu; other tertiary and higher metal oxides doped with divalent or trivalent europium, including functional groups such as molybdates, niobates or tungstates. Of course, other conversion materials that may be known to those of skill in the art may also be used to fill the cavity(ies) described herein.

Without limitation, the cavity(ies) formed above a die are preferably filled with a polymer (e.g., silicone, epoxy, etc.) containing one or more of the forgoing conversion materials. In such instances, the polymer containing the conversion material may be deposited in a cavity and then cured. Of course, the use of conversion-material-filled polymers is exemplary only, and any type of conversion material may be used. For example, a conversion material may be deposited in a cavity formed above a die, e.g., using one or more of physical vapor deposition, chemical, vapor deposition, epitaxy, sputtering, pulsed laser deposition, or another deposition technique.

The concept of filling a cavity above a die is illustrated in FIG. 2J. As shown, conversion material 210 fills cavity 209 (shown in FIG. 2H). In this instance, conversion material is in contact with an upper surface of die 206, which in this case may be a bare LED die. Such configuration may be understood to define a chip level conversion structure. Of course, such structure is not required. Indeed, the conversion material may be positioned at a distance away from the upper surface of die 206 (i.e., “remote from” a light emitting surface thereof), so as to define a remote conversion structure.

For the sake of clarity and ease of understanding, FIGS. 2A-2J illustrate the formation of an exemplary electronic assembly using a subassembly film 201 and a base layer 202 that are approximately the same size, wherein the base layer 202 defines a single subassembly connection point. It should be understood that such configuration is exemplary only, and that subassembly film 201 and base layer 202 need not be the same size. Indeed, base layer 202 may be significantly larger than subassembly film 201. In such instances, base layer 202 may include electrical contacts/traces 205 that define one or a plurality subassembly connection sites. Regardless, subassembly film 201 may be sized such that contacts/traces 204 overlap at least a portion of contacts/traces 205 at a particular subassembly connection site on base layer 202.

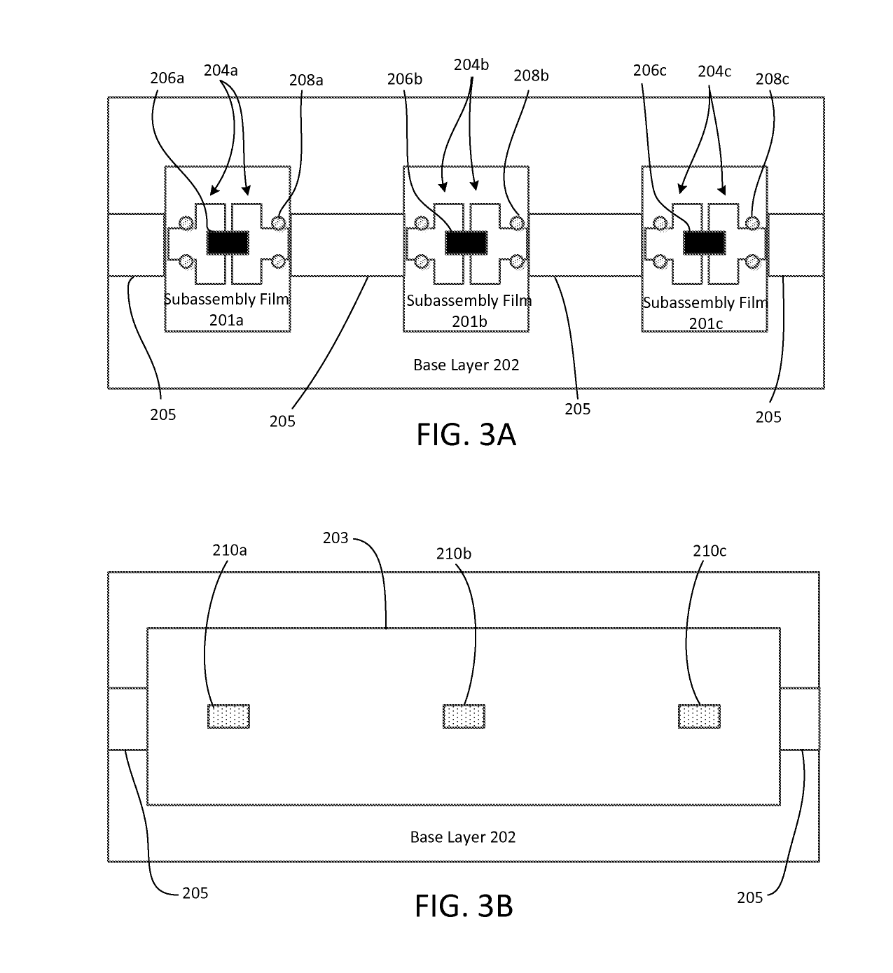

A non-limiting example of this concept is illustrated in FIG. 3A, wherein three first subassemblies composed of subassembly films, 201a, 201b, 201c and corresponding contacts/traces 204a, 204b, 204c, dies 206a, 206b, 206c are illustrated. As shown, each of the first subassemblies are positioned above respective subassembly connection sites (not labeled) defined by contacts/traces 205 of base layer 202, such that contacts/traces 204 overlap at least a portion of traces contacts 205 at their respective sites. Contacts/traces 204 are connected to contacts/traces 205 via conductive material 208a, 208b, 208c, as previously described.

Of course, the embodiment illustrated in FIG. 3A is exemplary only. Indeed, the base films described herein may define any number of subassembly connection sites and the number and configuration of the first subassemblies applied to the base film may vary widely. Indeed, the present disclosure envisions embodiments wherein a single base film includes connection sites for 1, 5, 10, 20, 50, 100 or more first subassemblies, and a corresponding number of first subassemblies are attached to such base film as described previously.

In embodiments wherein a single base film supports multiple first subassemblies, the coverlay may be configured to cover all or a portion of the first subassemblies. Without limitation, a single coverlay is preferably configured to cover all of the first subassemblies on a base film. This concept is illustrated in the non-limiting embodiment of FIG. 3B, wherein coverlay 203 covers all of subassembly films 201a, 201b, 201c, and includes openings (not labeled) corresponding to each of dies 206a, 206b, and 206c. Each of those openings may be filled e.g., with a transparent material or a conversion material, such as conversion material 210a, 210b, 210c in FIG. 3B. In such instances, the materials used to fill such openings may be the same or different. Alternatively or additionally, all or a portion of the openings may remain unfilled.

For ease of reference, the combination of a base layer, first subassembly, and a cover film is referred to herein as a second subassembly, whether or not a cavity above a die is filled. In some embodiments, a single second subassembly may form all or a part of an electronic device, such as a lighting panel, an area array panel, or a combination thereof. In such instances, it may be desired to use the second subassembly for its purpose with limited or no further processing. In this regard, the second subassembly may be connected to device circuitry and/or a power source, e.g., via one or more solder points, conductive materials, conductive paste, conductive ink, wires, combinations thereof and the like. That is, the method shown in FIG. 1 may proceed from block 108 or optional block 109 to optional block 111, wherein the second subassembly is connected to device circuitry and/or a power source.

Without limitation, connection of a second subassembly to device circuitry and/or a power source is preferably accomplished with one or more conductive materials, such as a conductive metal, solder, paste, paint, or combination thereof. For example, contacts/traces 205 of base film 202 may be electrically connected to appropriate contacts/traces on device circuitry and/or a power source by soldering contacts/traces 205 to contacts/traces of driving electronics and/or a power source. The method may then proceed to block 112 and end.

Alternatively or additionally, the second subassembly may not be capable of independently functioning as an electronic assembly, or may be connected to additional second subassemblies to form a more complex electronic assembly. In such instances, the method shown in FIG. 1 may proceed from block 108 or optional block 109 to optional block 110, wherein multiple subassemblies are electrically connected.

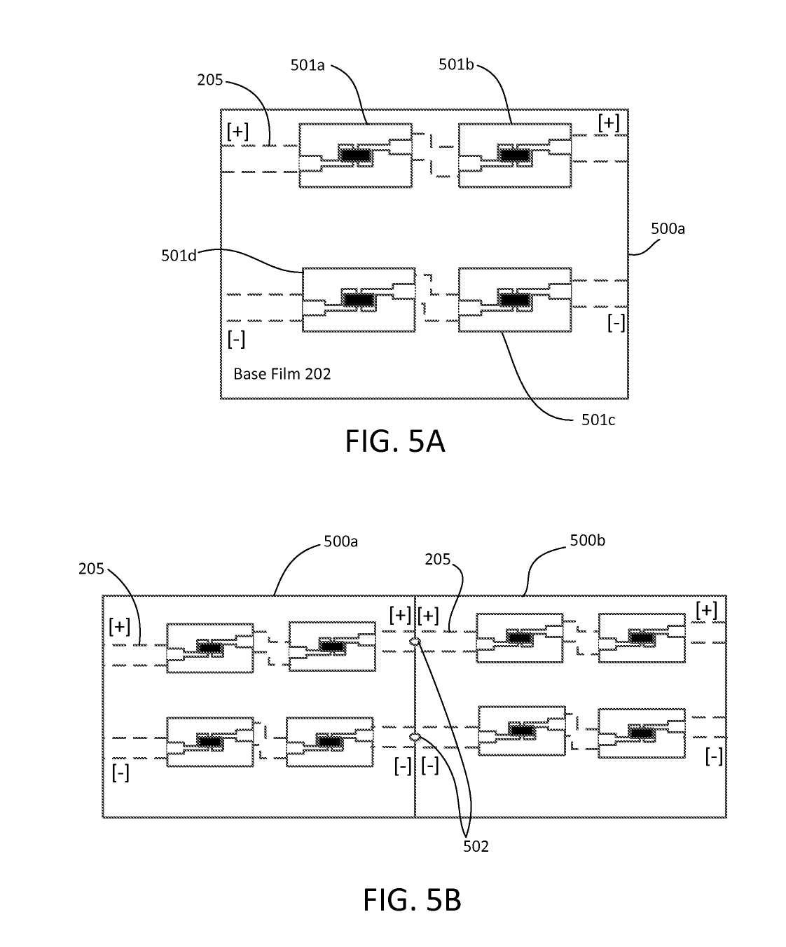

A non-limiting example of this concept is illustrated in FIGS. 5A and 5B. FIG. 5A depicts an exemplary single second subassembly 500a, which includes four first subassemblies 501a, 501b, 501c, 501d bound to base film 202 at respective subassembly connection sites (not shown) defined by contacts/traces 205. Each of the first subassemblies includes a subassembly film, macro and micro traces, and a die. The nature and configuration of such components is the same as described above for FIG. 4A. Accordingly, such components are not labeled in FIGS. 5A and B, and are not re-described here. As further shown in FIG. 5A, contacts/traces may terminate at an edge of base film 202, where there may be joined to corresponding contacts/traces of other second subassemblies, and/or to other components of an electronic device, and/or to a power source. For the sake of illustration, contacts/traces 205 are illustrated with plus a minus signs to denote their ability to be connected to positive or negative terminals of a power source.

A plurality of second subassemblies may be joined to one another by electrically connecting contacts/traces 205 of one second assembly to corresponding contacts/traces of another second assembly. This concept is illustrated in FIG. 5B, wherein second subassembly 500b is connected to second subassembly 500a via fasteners 502. Fasteners 502 may be configured to electrically connect contacts/traces 205 of adjacent second subassemblies. Accordingly, fasteners 502 may be formed from a conductive material, such as the conductive materials specified above for electrically connecting contacts/traces 204 to contacts/traces 205. In some embodiments, fasteners 502 are in the form of a weld, a soldering point, a bump, a wire, a paint, or a combination thereof, any of which may include conductive material as previously described. Without limitation, fasteners 502 are preferably formed from the CP-300 conductive interconnect paste available from Hitachi chemical.

For the sake of each of understanding, FIG. 5B depicts the connection of two second subassemblies, 500a and 500b. It should be understood that this illustration is exemplary only, and that any number of second subassemblies may be joined to one another, e.g., from 2 to 1000, 2 to 500, 2 to 100, 2 to 50, or even 2 to 10.

In some embodiments, each second subassembly may form a portion of a lighting device, such as an area array lighting panel. By combining a plurality of second subassemblies as previously described, lighting panels having any number second subassemblies may be formed. As a result, the methods described herein may be tailored to connect any number of second subassemblies, so as to form a lighting panel of a desired size and/or geometry.

As may be appreciated from the foregoing, the present disclosure describes a modular approach to forming electronic assemblies. In such methods, automated placement of dies on a subassembly film (e.g., using a surface mount attachment machine) may be performed accurately and rapidly, due to the ability to place the subassembly film in close proximity to a source of dies. Rapid placement and joining of the resulting first subassembly to a base film may then be achieved with less sensitive processes/equipment, due to the use of macro traces on the subassembly film, and macro traces at corresponding subassembly connection points on the base film. As a result, the methods described herein may enable the production of electronic subassemblies, without the need for manual inspection of the placed dies. This may be true even when a microelectronic die is placed on corresponding small die placement location on a subassembly film.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A method of manufacturing an electronic assembly, comprising:
forming a first subassembly by placing an electronic die at a die placement location on a subassembly film having a first upper and a first lower surface, said die placement location defined by first contacts/traces on said upper surface;
forming a second subassembly by placing said first subassembly on a base layer having a second upper surface and second lower surface, the base layer comprising second contacts/traces on said second upper surface, and joining said first subassembly to said base layer; and
electrically connecting said first contacts/traces and said second contacts/traces.

2. The method of claim 1, further comprising bonding said die to said subassembly film using at least one of a metal, a conductive solder, a conductive paste, a conductive ink, or a combination thereof.

3. The method of claim 1, wherein joining said first subassembly to said base layer comprises contacting said first lower surface with said second upper surface, and bonding said first subassembly layer and said base layer by applying heat, by applying pressure, with an adhesive, with a fastener, or a combination thereof.

4. The method of claim 3, wherein joining said first subassembly to said base layer comprises contacting said first lower surface with said second upper surface, and bonding said first subassembly and said base layer by applying a combination of heat and pressure.

5. The method of claim 1, wherein said die placement location is defined by a first gap in said first contacts/traces, wherein said first contacts/traces on either side of said first gap contact corresponding bond pads on said electronic die, when said electronic die is placed on said subassembly film.

6. The method of claim 5, wherein said second contacts/traces define a subassembly connection point on said base layer, said subassembly connection point defined by a second gap in said second contacts/traces.

7. The method of claim 6, wherein said first contacts/traces at said die placement location comprise a combination of micro traces and first macro traces.

8. The method of claim 6, wherein said micro traces define said first gap, and said first macro traces extend from said micro traces on one or both sides of said first gap so as to define at least one first region for electrically connecting to said second contacts/traces on said base film at either side of said second gap.

9. The method of claim 6, wherein simultaneous or subsequent to said joining, the method further comprises:
contacting said first lower surface with said second upper surface such that at least a portion of said first contacts/traces one on one or both sides of said first gap overlap with said at least a portion of said second contacts/traces defining said second gap.

10. The method of claim 9, wherein electrically connecting said first contacts/traces with said second contacts/electrodes comprises:
forming a via through said subassembly film; and
filling said via with conductive material, such that said conductive material electrically connects said first contacts/traces with said second contacts/traces.

11. The method of claim 1, further comprising joining a cover film to said second subassembly.

12. The method of claim 11, wherein said cover film comprises an opening, and the method further comprises placing said cover film such that said opening frames an upper surface of said die.

13. The method of claim 12, wherein said cover film and said upper surface of said die define a cavity above said die.

14. The method of claim 11, further comprising filling said cavity with a transparent material, a wavelength conversion material, or a combination thereof.

15. The method of claim 13, wherein said die comprises a light emitting diode (LED) die having a light emitting surface capable of emitting primary light of a first wavelength of wavelength range.

16. The method of claim 15, further comprising filling at least a portion of said cavity with a wavelength conversion material capable of converting said primary light to secondary light of a second wavelength or second wavelength range.

17. The method of claim 1, wherein:
said electronic die is placed on said die placement location with a first automatic placement system having a first placement accuracy;
said first subassembly is placed on said base film using a second automatic placement system having a second placement accuracy; and
said second placement accuracy is less than said first placement accuracy.

18. The method of claim 1, further comprising joining a plurality of said second subassemblies to form at least a portion of an electronic device.

19. The method of claim 18, wherein said electronic device is an area array lighting panel.

20. The method of claim 1, wherein said subassembly film comprises a polyester, an epoxy, an epoxy composite, a polyimide, polyamide, an acrylate, a copolymer, and combination thereof.

21. The method of claim 1, wherein said subassembly film comprises polyethylene terephthalate.

22. The method of claim 20, wherein said base film subassembly film comprises a polyester, an epoxy, an epoxy composite, a polyimide, polyamide, an acrylate, a copolymer, and combination thereof.

23. The method of claim 22, wherein said subassembly film and said base film are flexible, rigid, or a combination thereof.

24. The method of claim 23, wherein said subassembly film and said base film are both flexible.
